(19) United States
(12) Patent Application Publication
(10) Pub. No.: US 2025/0042725 A1
(43) Pub. Date: Feb. 6, 2025

(54) MICRO SYSTEM AND MANUFACTURING METHOD

(71) Applicant: AUDIO PIXELS LTD., Rehovot (IL)

(72) Inventors: Dmitri LURIE, Rehovot (IL); Menachem HOREV, Gdera (IL); Yuval COHEN, Cherrybrook, New South Wales (AU); Daniel LEWIN, Ramat HaSharon (IL); Yogev MOR CHAIM, Yavne (IL); Rephael HALACHMY, Rehovot (IL)

(21) Appl. No.: 18/722,752

(22) PCT Filed: Dec. 21, 2022
(86) PCT No.: PCT/IL2022/051362

§ 371 Date: Jun. 21, 2024

(30) Foreign Application Priority Data
Dec. 23, 2021 (EP) 21217618.4

(51) Int. Cl. B81C 1/00; B81B 3/00

(52) U.S. Cl. CPC B81C 1/00476; B81B 3/0021; B81B 2203/0127; B81C 2201/0133

(57) ABSTRACT

The present disclosure provides a method for use in manufacturing a microsystem, the method comprising forming an array of pillars in a thickness of a substrate, an area surrounding the array of pillars defining a cavity in the substrate; transforming at least some of the pillars into a sacrificial material; and depositing a sacrificial material layer using a non-conformal deposition process to fill up the cavity while enclosing hollow channels between the pillars of the pillars array, thereby obtaining a cavity filled with an etching facilitator arrangement.

### TECHNOLOGICAL FIELD

The present disclosure relates to the field of micro-electro-mechanical system (MEMS) manufacturing processes. In particular, the present disclosure relates to a method useful in manufacturing a microsystem, a method of manufacturing a MEMS and a MEMS obtained by said method.

### BACKGROUND

MEMS are commonly employed in a wide range of applications such as automotive, consumer, industrial and medical, as well as many other applications.

MEMS devices typically comprise a MEMS structure made of one or more functional layers (typically Polycrystalline Silicon or Metal) and sacrificial layers (typically Silicon dioxide or organic materials). MEMS structures can be of various types and depend on the intended MEMS function.

During the manufacturing process, the sacrificial layers are selectively removed in a process called “release” (for example: Silicon dioxide is chemically etched away by hydrofluoric acids), leaving the MEMS structure suspended in air so that it is able to perform its intended function.

While an etchant during the release process removes preferentially the sacrificial layers, the etchant can as well damage the functional layers due to a finite selectivity of the sacrificial layers over the functional layers. Therefore, the release time is usually limited, to limit damage to the MEMS functional layers. In order to address this issue, a typical MEMS design with a large MEMS structure element (e.g. superior to 100 μm²) includes apertures through said element with a relatively high density so as to provide several pathways for the etchant to remove the underlying sacrificial layer(s) in a limited time and avoid damaging the functional layers.

MEMS devices with a large MEMS structure element and without apertures or with a low density of apertures are difficult to release and their release may cause damage to the device during a prolonged release process.

There are many MEMS devices that comprise a cavity embedded in a substrate and a functional MEMS structure element (also referred to as mechanical element) suspended above the cavity. The conventional way to create such a cavity is by etching the entire thickness of the substrate from the back to create a through-substrate cavity. In that case, if there is a need to release a sacrificial layer which is located under a non-perforated functional layer, the required release etchant is introduced from the through-substrate cavity i.e. from the backside of the substrate.

While allowing a release of the MEMS structure with large area elements, the through-substrate cavity introduces many processing complications, including front to back alignment of the substrate, a need for flipping the substrate and exposing its front surface where the MEMS device is fabricated to the fabrication machinery, compromising the mechanical integrity of the substrate that may break under the stresses introduced during the fabrication of the MEMS device layers, and design constrains including a lack of control of the cavity depth and width limiting device density.

For example, U.S. Pat. No. 8,580,596 provides a method of forming a microcavity in a micro-electrical mechanical system (MEMS). The method disclosed includes providing a plurality of release openings through a backside of a substrate at the microcavity, etching through the release openings and forming a hermetic sealing layer on the backside of the substrate to seal the microcavity formed by etching.

As explained above, backside processing involves several constraints on the manufacturing process as well as on the resulting MEMS device. Therefore, there is a need in the art for alternative methods useful in MEMS device manufacturing.

### GENERAL DESCRIPTION

The present disclosure relates to a method useful in manufacturing a MEMS device including a MEMS structure having a suspended functional layer (typically made of Polycrystalline Silicon) above a cavity and/or a MEMS structure that requires a suspended functional layer above an air gap.

The present disclosure provides a method for use in manufacturing a microsystem. The method comprises forming an array of pillars in a thickness of a substrate, a volume enclosing the array of pillars defining a cavity in the substrate; transforming at least some of the pillars into a sacrificial material; depositing a sacrificial material layer using a non-conformal deposition process to fill up the cavity while encasing hollow channels between the transformed pillars of the pillars array, thereby obtaining a cavity filled with an etching facilitator arrangement. The step of forming the pillars array may be performed using etching processes, for example dry etching processes. The step of transforming at least some of the pillars into a sacrificial material may be performed using an oxidation processing. The step of depositing non-conformally a sacrificial material layer may be followed by a step of withdrawing the sacrificial material using a wet etching processing, thereby making said cavity empty.

In some embodiments, forming the array of pillars in a thickness of a substrate comprises: patterning the substrate to form a mask layer defining an array of features; and etching the patterned substrate around said features to form the pillars array beneath the features array and the cavity surrounding the pillars array, the cavity including a plurality of trenches between the pillars of the pillars array. In other words, the plurality of trenches may form a mesh of trenches. In other words, the shape of the array of features may define a cross-sectional shape of said pillars array in a plane parallel to the substrate surface.

In some embodiment, patterning of the trenches may be performed instead of patterning the features. The trenches may extend across the cavity area to form the outline of the cavity.

In some embodiments, the mask layer may further include a cavity outline and the array of features is within said cavity outline.

In some embodiments, the method may further comprise a step of removing the mask layer before the step of transforming at least some of the pillars into a sacrificial material.

In some embodiments, at least some of the features in the features array have a shape of a stem including at least one arm extending outwards.

In some embodiments, at least some of the features in the features array have a shape of a stem with at least three arms extending outwards.

In some embodiments, transforming at least some of the pillars into a sacrificial material includes fully transforming each pillar of the pillars array into sacrificial material.

In some embodiments, transforming at least some of the pillars into a sacrificial material includes partially transforming one or more pillars of the pillars array into sacrificial material.

In some embodiments, forming an array of pillars in a thickness of a substrate includes forming a plurality of pillar clusters and wherein the cavity comprises a plurality of sub-cavities each enclosing a pillar cluster of the array of pillars.

In some embodiments, at least some of the hollow channels are interconnected and form at least one network of interconnected channels.

In some embodiments, at least some of the hollow channels are interconnected and form several networks of interconnected channels.

In some embodiments, at least one hollow channel is not connected with the other hollow channels.

In some embodiments, the method further comprises (d) flattening of the top surface of the filled cavity filled with the etching facilitator arrangement.

In some embodiments, the substrate is made of silicon, the step of transforming into a sacrificial material includes an oxidation process and the non-conformal sacrificial material layer deposition includes a non-conformal silicon-dioxide layer deposition.

In another aspect, the present disclosure provides a method of manufacturing a micro-electro-mechanical system (MEMS) device comprising at least one suspended MEMS structure. The method comprises: forming a substrate with a cavity filled with an etching facilitator arrangement according to any of the methods described therein and any of their embodiments; forming by micromachining the at least one MEMS structure above the at least one cavity filled with the etching facilitator arrangement, said at least one MEMS structure including one or more pathways therethrough providing access to the etching facilitator arrangement; and etching through said one or more pathways to reach the hollow channels so as to spread an etchant material through the channels and remove the sacrificial material from the filled cavity, thereby suspending the at least one MEMS structure over the (emptied) cavity. In other words, the etchant may spread within the channels of the facilitator arrangement thereby etching the transformed pillars and sacrificial material. This leads to an (at least partially) empty cavity over which the MEMS structure is suspended.

In some embodiments, the method further comprises (IV) depositing one or more additional sacrificial layers to fill the one or more pathways in the MEMS structure. The depositing step may be performed without fully filling the cavity.

In some embodiments, the method further comprises forming a second MEMS structure above said at least one MEMS structure.

In some embodiments, the at least one MEMS structure comprises a plurality of adjacent MEMS structures.

In another aspect, the present disclosure provides a method of manufacturing a micro-electro-mechanical system (MEMS) device comprising at least one suspended MEMS structure. The method comprises: forming a substrate with a cavity filled with a sacrificial material including one or more hollow channels embedded into said sacrificial material; forming by micromachining the at least one MEMS structure above the at least one cavity filled with the sacrificial material, said at least one MEMS structure including one or more pathways therethrough providing access to the filled cavity; and etching through said one or more pathways to reach the hollow channels so as to spread an etchant material therethrough and remove the sacrificial material from the filled cavity, thereby suspending the at least one MEMS structure over the cavity.

In some embodiments, at least some of the one or more hollow channels are interconnected.

In another aspect, the present disclosure provides a micro-electro-mechanical system (MEMS) device obtained by the methods of manufacturing a MEMS device described hereinabove.

In some embodiments, the MEMS device is a sensor or an actuator such as a speaker.

In another aspect, the present disclosure provides a device for use in MEMS manufacturing including: a substrate; a cavity formed in a thickness of the substrate wherein said cavity is filled of sacrificial material, one or more hollow channels being embedded into said sacrificial material.

In some embodiments, at least some of the hollow channels are interconnected.

In some embodiments, the interconnected hollow channels form one or more channel networks.

In some embodiments, the substrate is made of silicon and the sacrificial material is made of silicon dioxide.

In another aspect, the present disclosure provides a device for use in MEMS manufacturing including: a substrate; a cavity formed in a thickness of the substrate wherein said cavity comprises a pillars array made of sacrificial material and wherein a non-conformal sacrificial layer is deposited over the cavity so as to embed one or more hollow channels between the pillars of the pillars array.

In some embodiments, at least some of the hollow channels are interconnected.

In some embodiments, the interconnected hollow channels form one or more channel networks.

In some embodiments, the substrate is made of silicon and the sacrificial material is made of silicon dioxide.

In the present application, the following terms and their derivatives may be understood in light of the below explanations:

As used herein, the term “cavity” may refer to a recess i.e. an open cavity. In particular, a substrate cavity may be open on one side only i.e. the cavity may not form a through-hole throughout the substrate thickness or an enclosed cell within the substrate.

As used herein, the term “MEMS” may refer to a micro electro mechanical system (also referred to as microsystems or micromachines). MEMS generally function as transducers. The term “transducer” may refer to an entity/device configured to transform one form of signal or energy into another form and may include both sensors and actuators. The term “sensor” may refer to an entity/device configured to measure information from a surrounding environment and to provide an electrical output signal in response to the parameter it measured. Examples of MEMS sensors may include accelerometers, gyroscopes, inertial measurement units, pressure sensors, temperature sensors, proximity sensor, humidity sensors, microphones, etc. The term “actuator” may refer to a device configured to convert an electrical signal into an action e.g., into a force to manipulate itself, other mechanical devices, or the surrounding environment to perform a predetermined function. Examples of MEMS actuators may include speakers, deflecting mirrors, pumps etc. A MEMS typically comprises a MEMS structure suspended above a cavity which is formed by sequential processes of, on the one hand, depositing and/or chemically transforming layers for forming both the (functional) layers of the desired MEMS structure and the layers yet to become sacrificial, and, on the other hand, removing the sacrificial layers during the manufacturing process.

As used herein, the term “wafer” may refer to a substrate. Generally, the substrate material is typically silicon, while other substrates may be used. Silicon can be readily oxidized to form a chemically inert and electrically insulating Silicon dioxide (SiO₂) on exposure to oxygen.

As used herein, the term “patterning” may refer to transferring of a master pattern (also referred to as “mask” or “photomask”) onto the surface of a substrate or on any process layer added on the substrate. A typical patterning Photolithography Process may involve the application of a light-sensitive photoresist layer followed by photoresist exposure through the mask and then developing the exposed photoresist, leaving a pattern on the wafer surface. In other words, photolithography may involve depositing a photoresist layer of an organic polymer, which is sensitive to ultraviolet radiation, on the substrate. A photomask, consisting of a glass plate (transparent) coated with a chromium pattern (opaque), may then be placed in contact with the photoresist coated surface. The wafer may then be exposed to light (e.g. ultraviolet radiation), thereby transferring the pattern on the mask to the photoresist which is then developed in a way very similar to the process used for developing photographic films. Alternatively, the photoresist may be exposed in a direct-write process using scanning lasers, electron-beams or other radiation sources. The radiation causes a chemical reaction in the exposed areas of the photoresist. There are generally two types of photoresist layer: positive and negative. Positive photoresist is strengthened by the radiation whereas negative photoresists are weakened. Thereafter, on developing, a rinsing solution may remove either the exposed areas (for a negative photoresist layer) or the unexposed areas (for a positive photoresist layer) of photoresist leaving a pattern of bare and photoresist-coated substrate on the wafer surface. In the present disclosure, the patterned photoresist layer may also be referred to as a mask layer. The resulting photoresist pattern is either the positive or negative image of the original pattern of the photomask. Generally, etching may then be performed for example to create trenches below the bare areas. The remaining photoresist may subsequently be removed, e.g. with hot sulfuric acid which attacks the photoresist but not the silicon.

As used herein, the term “feature” may refer to a spot (i.e. a closed plane shape) on a photomask. In particular, a feature array may geometrically form a repetitive pattern of spots of various shapes. In some embodiments, the features array may be spread on the photomask into one or more features clusters. In some embodiments, at least some of the features in the feature array have a shape including a stem and an arm extending outwards. In some embodiments, at least some of the features in the feature array have a shape including a stem and three or more arms extending outwards (i.e. a star-like shape). The Applicant has found that shapes including a stem and at least one arm extending outwards limit the displacement of the resulting pillars due to stress buildup in the following transforming (e.g. oxidation) process. The term “feature” may also be understood as a planar closed configuration.

In some embodiments, photolithography may preliminarily involve covering the substrate with an oxide layer, e.g. silicon dioxide (SiO2), in the case of silicon wafers, on which a pattern of holes is to be formed. These embodiments are generally referred to as “hard masking” embodiments. The rest of the photolithography follows generally the method described above: A photoresist layer of an organic polymer, which is sensitive to radiation, may be deposited on the oxide layer. The photomask may then be placed in contact with the photoresist coated surface. The wafer may then be exposed to the radiation, thereby transferring the pattern on the mask to the photoresist layer. Thereafter, a rinsing solution may remove either the exposed areas (for a negative photoresist layer) or the unexposed areas (for a positive photoresist layer) of photoresist leaving a pattern of bare and photoresist-coated oxides on the oxide layer i.e. forming the mask layer. The resulting photoresist pattern is either the positive or negative image of the original pattern of the photomask. A chemical (e.g. hydrochloric acid) may be used to attack and remove the uncovered oxide from the exposed areas of the photoresist. The remaining photoresist is subsequently removed, e.g. with hot sulfuric acid which attacks the photoresist but not the oxide layer on the silicon, leaving a pattern of oxide on the silicon surface.

As used herein, the term “etching” may refer to a subtractive process that involve removal of part of a material. Etching may be carried out to create grooves of different shapes for example using wet etching or dry etching methods.

Wet etching involves the removal of material through immersion in a liquid bath of a chemical etchant. Etchants can be isotropic or anisotropic. Isotropic etchants etch the material at the same rate in all directions, and consequently may lead to undercutting phenomenon i.e. removing of some material located below the etch masks. Examples of isotropic etchant may include hydrofluoric acids (HF) and nitric acid (HNO₃). Anisotropic etchants etch faster in a preferred direction. An example of anisotropic etchant includes potassium hydroxide (KOH). Structures formed in the substrate by anisotropic etchant may be dependent on the crystal orientation of the substrate.

Dry etching relies on vapor phase or plasma-based methods of etching using suitably reactive gases or vapors usually at high temperatures. Two examples of dry etching method for MEMS manufacturing are reactive ion etching (RIE) and deep reactive ion etching (DRIE). RIE may utilize radio frequency (RF) power to drive the chemical reaction. Energetic ions are accelerated towards the material to be etched within a plasma phase supplying additional energy needed for the reaction; as a result, the etching can occur at much lower temperatures (typically 1500-250° C., sometimes room temperature) than those usually needed (above 1000° C.). RIE is not limited by the crystal planes in the silicon, and as a result, deep trenches and pits, or arbitrary shapes with vertical walls can be etched. An etch rate (generally expressed in microns per minute) may depend on an etching method, an etching temperature, an etchant material and concentration and on the material to be etched. DRIE is similar to RIE with the expectation that the etching is performed in steps or stages and in between these steps, the side-walls of the trench are covered with a protective material that protects the sidewalls from the etching plasma, thus allowing deeper trenches or holes to be etched, compared to RIE.

As used herein, the term “structural layer” refers to a layer deposited on a wafer and made of a structural material (for example Polycrystalline Silicon (also referred to as Poly), silicon nitride or Aluminum) out of which a final structure is made.

As used herein, the term “sacrificial layer” refers to a layer that act as a temporary substance that is needed for the device's building process. Structural material may be a material that can be selectively removed without affecting (i.e. damaging) neighboring structural layers. The sacrificial material is finally etched away to release the final structure. For example, silicon-dioxide can be used as a sacrificial material when the structural material used is Polycrystalline silicon.

In the present disclosure the plane which is parallel to the silicon wafer surface is illustrated and referred to as the XY plane. It may also be called the device plane. The term “horizontal” refers to this plane. The term “vertical” refers to the direction which is perpendicular to the horizontal device plane, and it is indicated as the Z-axis in the figures. The terms “above” and “below” refer to differences in Z-coordinates. The terms “height” and “depth” refer to vertical distances (in the Z-direction), while “width” and “length” refer to horizontal distances (in either the X-direction or the Y-direction). Terms such as “vertical” or “horizontal” do not imply anything about the orientation of the silicon wafer when the MEMS device is manufactured, or when the device is in use. The device and the wafer may be oriented in any suitable direction during usage or manufacturing, for example sideways.

Further, unless specifically defined, the description of a layer being deposited or produced ‘on’ another layer or substrate, includes the options of said layer being produced or deposited directly on, i.e. in contact with, said other layer or substrate, and said layer being produced on one or a stack of intermediate layers between said layer and said other layer or substrate.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 illustrates a cross sectional view of steps of a first part of a method for manufacturing a MEMS device according to some embodiments of the present disclosure;

FIG. 2 illustrates a top view the steps illustrated in FIG. 1;

FIG. 3 illustrates a cross sectional view of some further steps of a method for manufacturing a MEMS device according to embodiments of the present disclosure;

FIG. 4 illustrates a top view the steps illustrated in FIG. 3;

FIG. 5 illustrates a cross sectional view of a MEMS device according to other embodiments of the present disclosure;

FIG. 6 illustrates a step of enclosing hollow channels according to some embodiments of the present disclosure.

### DETAILED DESCRIPTION OF EMBODIMENTS

The present disclosure provides a novel technique for forming a cavity embedded in a substrate such as a silicon wafer. In particular, the cavity in the present disclosure may be efficiently formed in a single wafer layer. In other words, bottom and peripheral walls of the cavity may be formed in a unitary substrate.

Generally, a method for manufacturing a MEMS device (such as transducer, a sensor or an actuator) according to the present disclosure can be split into two parts.

In a first part, a cavity filled with an etching facilitator arrangement is formed within a substrate. The etching facilitator arrangement facilitates subsequent etching for example by allowing for a quicker etching compared to the etching of a cavity of similar dimensions but filled with sacrificial material layer without hollow channels, all other etching parameters being similar. The etching facilitator arrangement may include hollow channels enclosed (encircled) in the sacrificial material. Hollow channels enclosed in the sacrificial material improve spreading of the etchant and vacation of the etching products by significantly increasing the etched surface area. Spreading of the etchant through the hollow channels allows exposing concealed areas of the sacrificial material in the cavity i.e. area which are not directly accessible to the etching material through pathways in a MEMS structure suspended above the cavity. This allows providing a faster etching. The hollow channels may be interconnected. Interconnected hollow channels in the sacrificial material allow spreading of the etchant to other parts of the filled cavity when the etchant reaches a hollow channel. For example, the hollow channels may be formed by depositing a non-conformal (low conformity) sacrificial material layer(s) on an array of pillars made of sacrificial material (or more generally on a set of structures extending vertically within the cavity made of sacrificial material).

In a second part, a MEMS structure is formed above the filled cavity. The MEMS structure includes one or more pathways therethrough in order to allow the etching material to reach the cavity filled with the etching facilitator arrangement. The MEMS structure is formed using micromachining techniques i.e., by addition or subtraction of one or more layers of structural and/or sacrificial materials using photolithography and etching techniques. The filled cavity is etched through said one or more pathways so that an etchant material reaches the hollow channels and spreads therethrough thereby removing the sacrificial material from the filled cavity. This enables suspending the at least one MEMS structure over the cavity.

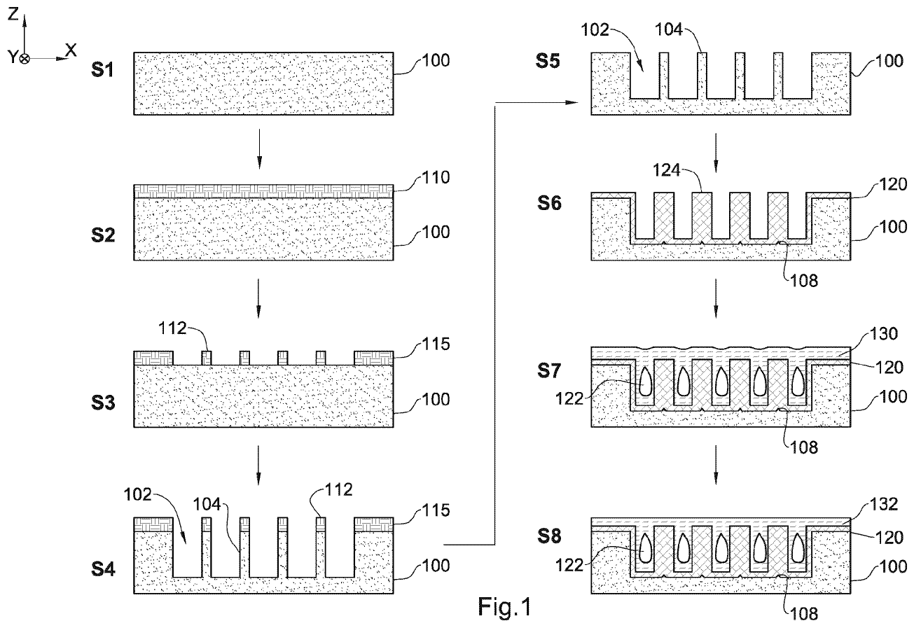

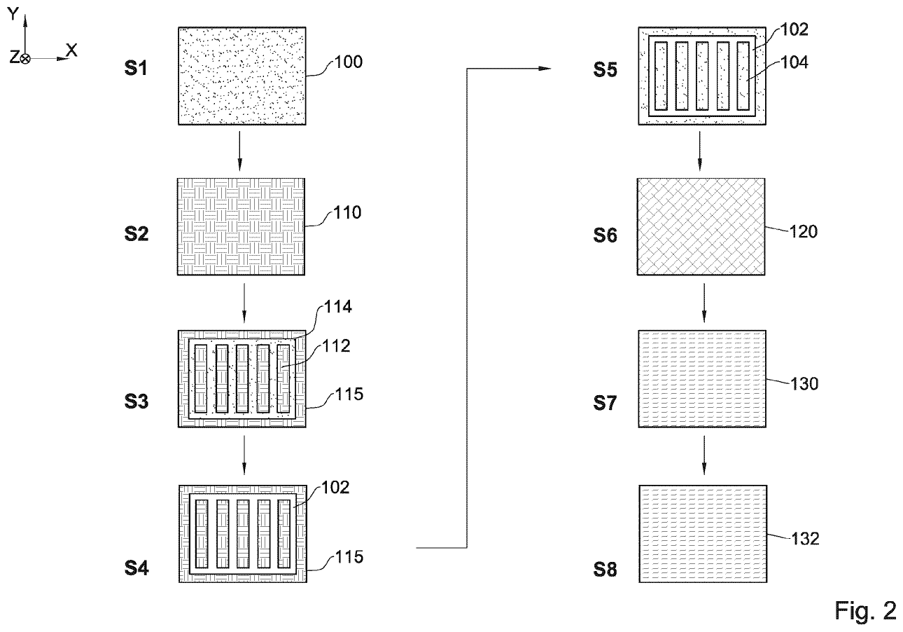

FIG. 1 and FIG. 2 respectively illustrate a cross sectional view and a corresponding top view of the steps of an exemplary method for use in micro-electro-mechanical system (MEMS) manufacturing according to some embodiments of the present disclosure. In view of the explanations given hereinabove, FIG. 1 and FIG. 2 can be similarly seen as an exemplary first part of a method for manufacturing a micro-electro-mechanical system (MEMS) device comprising at least one suspended MEMS structure according to some embodiments of the present disclosure.

In a first step S1, a substrate 100 is provided.—In the present example, the substrate may be made of Silicon.—The substrate may for example be a silicon wafer. It is understood that the present description would also apply to a substrate made of a different material provided oxidation processes are modified to an appropriate method of transforming the substrate material into a sacrificial material and oxide layer deposition processes are modified to an appropriate sacrificial material layer deposition process. For example, the substrate material may be made of an alloy of Ge/GeSi. Ge/GeSi may be oxidized into GeO₂ which can be etched via HBr or water.

In a second step S2, a photoresist layer 110 may be deposited on the substrate. The photoresist material may be an organic polymer, which transforms into a soluble material after exposure to radiation.

In a step S3, a photomask may then be placed in contact with the photoresist coated surface. The photomask may comprise a transparent plate (e.g. made of glass) coated with an opaque pattern (e.g. made of chromium). The photomask may define a pattern including an array of features. The photomask may include a cavity outline surrounding the array of features. Generally, the features array may geometrically form a repetitive pattern of spots of various shapes. In some embodiments, the features array may be spread on the photomask into one or more features clusters. For example, the features may comprise a pattern including rectangular features and cross shaped features. The wafer 100 may then be exposed to radiation (e.g. ultraviolet light), thereby transferring the photomask pattern on the photoresist layer. After rinsing, the mask layer 115 therefore defines an array of features 112 within a cavity outline 114 (visible on FIG. 2). As explained above, in some embodiments, the array of features on the photomask is spread into a plurality of features clusters and the mask layer includes a corresponding plurality of features clusters. The intermediate product obtained at step S3 i.e., a substrate having a mask layer defining an array of features transferred thereto by using a photomask may be referred to in the present disclosure as a patterned substrate and the process of steps S1 to S3 may be referred to altogether as the patterning of the substrate.

Returning to FIGS. 1-2, in a further step S4, etching of the patterned substrate is performed. Preferably, the etching process is a high-ratio non-isotropic silicon etching process such as Deep Reactive Ion Etching (DRIE) process. Because the mask layer 115 defines a protective array of features 112, etching of the patterned substrate is performed around the features of the array of features 112. The etching therefore forms at least one cavity embedded in the substrate comprising a mesh of trenches 102 and an array of pillars 104. The cavity surrounds the array of features 112. It is understood that in some embodiments in which the array of features on the mask layer comprises a plurality of features clusters, the etching process may cause the formation of a corresponding plurality of cavities surrounding the plurality of features clusters. The mesh of trenches 102 results from etching of the areas of the substrate not protected by the mask layer 115. The mesh of trenches 102 may form a shared volume of continuous gaps. The pillars array 104 is formed beneath the features array 112 as the irradiated photoresist material of the features array 112 prevents etching of the substrate.

In a further step S5, the mask layer 115 is removed from the substrate 100.

In a further step S6, at least some of the pillars of the pillars array 104 are fully oxidized. At least some of the pillars are fully transformed into Silicon Dioxide. As illustrated on FIG. 1, the substrate 100 may be oxidized until all the pillars are fully oxidized and form an oxidized pillars array 122. In other words, the furnace oxidation may be a self-limiting process where oxidation continues as long as there is silicon available. In some embodiments, one or more of the pillars are partially oxidized. For example, when the features in the features array have different dimensions, the resulting pillars created by the etching process also have different volumes. Therefore, the oxidation process may be controllably performed until only some of the pillars are fully oxidized. The oxidation process of step S6 may be a furnace oxidation process such as Atmospheric Pressure Chemical Vapor Deposition or Low Pressure Chemical Vapor Deposition. In the oxidation process of step S6, a gas source may only contain Oxygen and the Silicone may be consumed by the oxidation. The furnace oxidation process of step S6 therefore transforms the pillars array of Silicon into an oxidized pillars array of Silicon Dioxide. As a consequence of the oxidation process, the volume of the oxidized pillars is enlarged in comparison with the pillars array of step S5. Furthermore, dents 108 of substrate material may be formed at the feet of the oxidized pillars 124. Generally, the dents 108 may form protrusions extending from the substrate surface into the oxidized pillars 124, for example along a central axis of the oxidized pillars 124.

In a further step S7, the at least one cavity filled with an etching facilitator arrangement is obtained by depositing one or more low conformal sacrificial oxide layers on the intermediate product originating from step S6. Low conformal oxide layers are deposited so as to fill up the at least one cavity while enclosing hollow channels 122 in the mesh (net) of trenches 102 surrounding the oxidized pillars array 124. Low conformal oxide layers may be deposited for example according to the Plasma Enhanced Chemical Vapor Deposition process using SiH₄ and O₂. Low conformal deposition tends to deposit more material at the top of the pillars than at the bottom. FIG. 6 is a schematic illustration of a low conformal layer deposition process of oxide on an oxidized pillar array 420 represented as oxide layer 430. As can be seen, the non-conformal layer 430 forms an uneven layer on the pillars 420. More precisely, the first non-conformal layer 430 causes an accumulation of oxide at a head of the pillars 420. The accumulation of oxide at the head of the pillars prevents an even deposition of oxide at the feet of the pillars 420 and leads to the creation of a hollow channel 422 between the oxidized pillars 420. The enclosed grid of the oxidized pillars 124 forms a net of interconnected hollow channels 102. This improves the spreading of an etchant in a subsequent step described hereinbelow.

In a further optional step S8, the surface of the non-conformal oxide layer facing away from the substrate is flattened. Preferably, the flattening may be achieved by a Chemical Mechanical Polishing (CMP) process and does not reach the hollow channels.

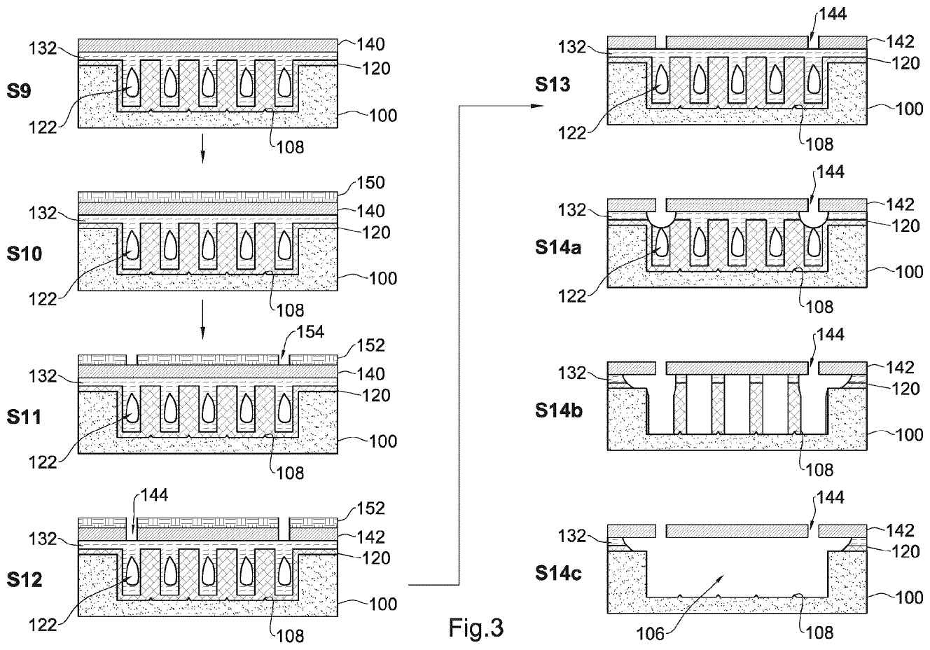

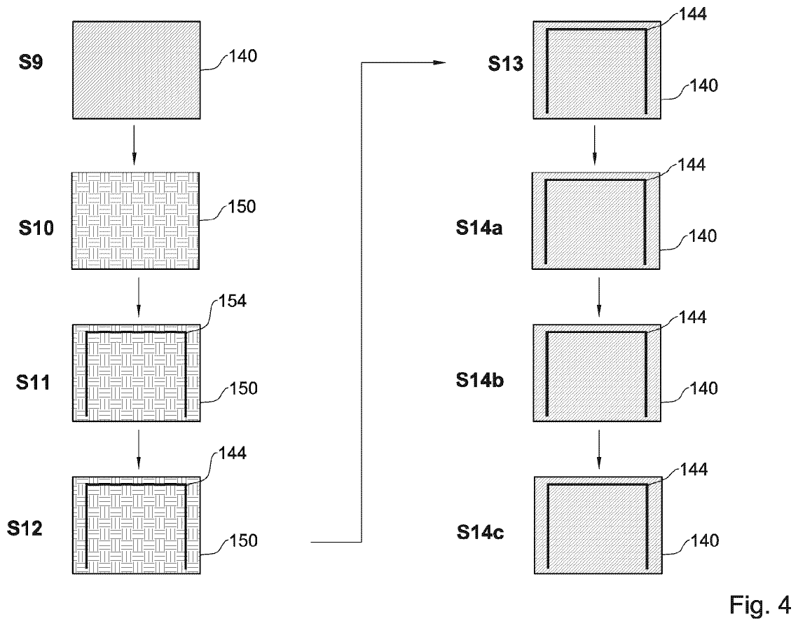

FIG. 3 and FIG. 4 respectively illustrate a cross sectional view and a corresponding top view of steps of an exemplary second part of a method for manufacturing a micro-electro-mechanical system (MEMS) device comprising at least one suspended MEMS structure according to some embodiments of the present disclosure.

The second part of the method for manufacturing a MEMS device according to the present disclosure may comprise many variations since it encompasses manufacturing of various types of MEMS such as transducers, sensors, actuators of different types.

In the illustrated example, in a step S9, a structural layer 140 made of polysilicon is deposited on the intermediate product obtained from step S8 (i.e. the substrate with a cavity filled with the etching facilitator arrangement made of the oxide pillars array, hollow channels and flattened low conformal oxide layer(s)). The structural layer may form a first plate of the MEMS device.

In a further step S10, a photoresist layer 150 may be deposited on the intermediate product resulting from step S9. The photoresist material may be an organic polymer, which is sensitive to ultraviolet radiation.

In a further step S11, a photomask may then be placed in contact with the photoresist coated surface. The photomask of step S11 may define one or more pathway features. The pathway features may be configured so that after transfer on the photoresist layer, the pathway features form an opening in the mask layer preferably located above the cavity. The product may then be exposed to radiation, thereby transferring the pathway features on the photoresist layer. After rinsing, the resulting polysilicon layer 140 is patterned with a mask layer 152 defining a pathway feature 154 (i.e. an opening in the mask layer 152 preferably located above the cavity).

In a further step S12, etching of the patterned polysilicon layer 140 is performed until the etchant reaches the surface of the flattened low conformal layer 132 facing away from the substrate 100. Preferably, the etching process is a high-ratio non-isotropic silicon etching process such as Deep Reactive Ion Etching (DRIE) process. Because the mask layer 152 defines a pathway feature 154, etching of the patterned polysilicon layer 140 is performed down through the pathway feature 154. The resulting product comprises an etched polysilicon layer 142 defining a pathway 144 replicating a shape of the pathway feature 154 of the mask layer 152 into the polysilicon layer 142. Generally, the pathway(s) may provide access to the etching facilitator arrangement. In some embodiments, the pathway(s) may be located above the cavity filed with the etching facilitator arrangement.

In a further step S13, the mask layer is removed from the etched polysilicon layer 142.

In a further step S14a-S14c, further etching through the pathway 144 of the polysilicon layer 142 is performed. Preferably, the etching process is a high-ratio non-isotropic silicon etching process such as Deep Reactive Ion Etching (DRIE) process, for example using Hydrofluoric (HF) acid as an etchant. Step S14a-S14c is illustrated with several drawings for the purpose of showing the evolution of the etching over time rather than referring to different steps involving change of experimental conditions. As illustrated in S14a, etching through the pathway 144 of the polysilicon layer 142 creates grooves in the non-conformal oxide layer 132 which reach the hollow channels 122. The hollow channels 122 expand through the mesh of trenches 102 in between the oxidized pillars array 124. As explained above, the hollow channels are partially or fully interconnected i.e. there is a hollow route from one hollow channel to another because of the structure of the oxidized pillars array 124. Therefore, the hollow channels facilitate spreading of the etchant from above the pathway to the whole cavity filled with the etching facilitator arrangement. In fact, when the etchant reaches one hollow channel it can reach all interconnected channels and is therefore in contact with a higher surface of sacrificial material. In other words, the etchant (HF, for example) progresses rapidly through the channels that provide a route for the HF to reach the SiO₂ all over the cavity. As shown in S14b, the etchant spreads to the full cavity and the oxidized pillars array gets etched through the hollow channels. S14c illustrates the resulting MEMS device including a structural layer 142 (also referred to as a MEMS structure) suspended above the etched cavity 106 embedded in the substrate 100. Dents 108 remaining from the pillars array 104 may be observed on the bottom wall of the cavity 106.

Optionally, one or more additional micromachining steps can be performed such as depositing an additional oxide layer to fill the pathway 144, forming of an additional MEMS structure above the first MEMS structure (i.e. structural layer 142) or other layer deposition to form a MEMS speaker.

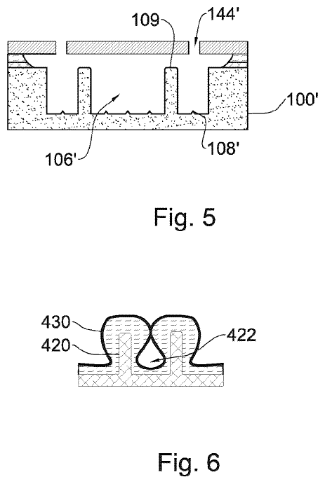

FIG. 5 shows a cross sectional view of a MEMS device obtained by a manufacturing method according to other embodiments of the MEMS manufacturing method in which some of the pillars of the pillars array are not fully oxidized. For the sake of conciseness, the description of FIG. 5 focuses on the elements which are differing with regard to previously described embodiments. The elements/steps which are identical or similar to elements/steps previously described are referenced by the same reference followed by an apostrophe (e.g. 100′) and the description given hereinabove with respect to these elements/steps apply similarly. FIG. 5 shows a MEMS device including a MEMS structure 142′ including a pathway 144′. The MEMS structure is suspended over a cavity 106′ embedded in a substrate 100′. A bottom wall of the cavity 106′ includes fragments of an etching facilitator arrangement used in the manufacturing process of said cavity 106′. Additionally, the substrate 100′ includes columns 109 which extend vertically from the bottom wall of the cavity. The columns 109 result from embodiments of the process described hereinabove in which the array of features includes features of different dimensions. In these embodiments, after patterning and etching of the substrate, an oxidation step may be performed so that the resulting pillar arrays on the substrate includes fully oxidized pillars and partially oxidized pillars. In these embodiments, after forming of the MEMS structure and pathway and etching of the etching facilitator arrangement, the partially oxidized pillars may form the columns 109.

The present disclosure enables facilitating fabrication of a MEMS device with a MEMS structure suspended above a cavity wherein the MEMS structure includes one or more pathways and an etching distance in the device plane between a projection of the one or more pathways on the device plane and at least some points of a projection of the cavity on said device plane is superior to 10 microns. In other words, the present disclosure facilitates manufacturing of devices in which an etchant would need to travel in a plane perpendicular to a main etching direction (i.e. the XY plane) for more than about 10 microns away from any of the one or more pathways.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. No feature described in the context of an embodiment is to be considered an essential feature of that embodiment, unless explicitly specified as such.

Although steps of methods according to some embodiments may be described in a specific sequence, methods of the invention may comprise some of the described steps carried out in a different order. A method of the invention may comprise all of the steps described or only a few of the described steps. No particular step in a disclosed method is to be considered an essential step of that method, unless explicitly specified as such.

Although the invention is described in conjunction with specific embodiments thereof, it is evident that numerous alternatives, modifications and variations that are apparent to those skilled in the art may exist. Accordingly, the invention so embraces all such alternatives, modifications and variations that fall within the scope of the appended claims. It is to be understood that the invention is not necessarily limited in its application to the details of construction and the arrangement of the components and/or methods set forth herein. Other embodiments may be practiced, and an embodiment may be carried out in various ways. In particular, in the second part of the method of manufacturing a MEMS comprising at least one suspended MEMS structure, the MEMS structure may be configured for the resulting MEMS to function as a transducer, a sensor or an actuator such as a MEMS speaker. It may include VIAs and interconnections between the layers, a second or further plate, etc. Furthermore, it is noted that some embodiments of the present disclosure may be directed to forming a cavity filled with an etching facilitator arrangement within a thickness of a structural material layer instead of in the substrate itself.

The phraseology and terminology employed herein are for descriptive purpose and should not be regarded as limiting. Citation or identification of any reference in this application shall not be construed as an admission that such reference is available as prior art to the invention. Section headings are used herein to ease for understanding of the specification and should not be construed as necessarily limiting.

1-15. (canceled)

16. A method for use in manufacturing a microsystem, the method comprising:
(a) forming an array of pillars in a thickness of a substrate, a volume enclosing the array of pillars defining a cavity in the substrate;
(b) transforming at least some of the pillars into a sacrificial material;
(c) depositing a sacrificial material layer using a non-conformal deposition process to fill up the cavity while encasing hollow channels between the transformed pillars of the pillars array, thereby obtaining a cavity filled with an etching facilitator arrangement.

17. The method according to claim 16, wherein forming the array of pillars in a thickness of a substrate comprises:
i) patterning the substrate to form a mask layer defining an array of features;
ii) etching the patterned substrate around said features to form the pillars array beneath the features array and the cavity surrounding the pillars array, the cavity including a mesh of trenches between the pillars of the pillars array.

18. The method according to claim 17, wherein the mask layer further includes a cavity outline and the array of features is within said cavity outline.

19. The method according to claim 16, wherein at least some of the features in the features array have a shape of a stem including at least one arm extending outwards.

20. The method according to claim 16, wherein at least some of the features in the features array have a shape of a stem with at least three arms extending outwards.

21. The method according to claim 16, wherein transforming at least some of the pillars into a sacrificial material includes fully transforming each pillar of the pillars array into sacrificial material.

22. The method according to claim 16, wherein transforming at least some of the pillars into a sacrificial material includes partially transforming one or more pillars of the pillars array into sacrificial material.

23. The method according to claim 16, wherein at least some of the hollow channels are interconnected in at least one network of interconnected channels.

24. The method according to claim 16, wherein at least one hollow channel is not connected with the other hollow channels.

25. The method according to claim 16, wherein the substrate being made of silicon, the step of transforming into a sacrificial material includes an oxidation process and the non-conformal sacrificial material layer deposition includes a non-conformal silicon-dioxide layer deposition.

26. A method of manufacturing a micro-electro-mechanical system (MEMS) device comprising at least one suspended MEMS structure, the method comprising:
I. forming a substrate with a cavity filled with an etching facilitator arrangement according to any of the preceding claims;
II. forming by micromachining the at least one MEMS structure above the at least one cavity filled with the etching facilitator arrangement, said at least one MEMS structure including one or more pathways therethrough providing access to the etching facilitator arrangement;
III. etching through said one or more pathways to reach the hollow channels so as to spread an etchant material through the channels and remove the sacrificial material from the filled cavity, thereby suspending the at least one MEMS structure over the cavity.

27. The method according to claim 26, further comprising (IV) depositing one or more additional sacrificial layers to fill the one or more pathways in the MEMS structure.

28. A micro-electro-mechanical system (MEMS) device obtained by the method according to claim 26.

29. The micro-electro-mechanical system (MEMS) device of claim 28, wherein the MEMS device is a sensor or an actuator such as a speaker.

30. A device for use in MEMS manufacturing including:
(a) a substrate;
(b) a cavity formed within a thickness of the substrate,
wherein said cavity comprises a pillars array made of sacrificial material, said pillars array having been deposited with a non-conformal layer of sacrificial material to fill said cavity while embedding one or more hollow channels between the pillars of the pillars array.
